(19) United States
(12) Patent Application Publication
(10) Pub. No.: US 2025/0165026 A1
(43) Pub. Date: May 22, 2025

(54) COMMAND SIGNAL CLOCK TOGGLING BY A CONTROLLER

(71) Applicant: Micron Technology, Inc., Boise, ID (US)

(72) Inventors: Leonid Minz, Beer Sheva (IL); Luigi Pilolli, L'Aquila (IT); Gyan Prakash, Bangalore (IN)

(21) Appl. No.: 18/949,101

(22) Filed: Nov. 15, 2024

Related U.S. Application Data
(60) Provisional application No. 63/602,034, filed on Nov. 22, 2023.

(51) Int. Cl. G06F 1/06

(52) U.S. Cl. CPC G06F 1/06

(57) ABSTRACT

A method includes providing, by a controller, a plurality of control signals and a first plurality of clock signals to a memory device. In some embodiments, the first plurality of clock signals is greater than the plurality of control signals. The method can also include receiving, at the controller, a first plurality of data signals corresponding to the plurality of control signals and a second plurality of clock signals corresponding to a first portion of the first plurality of clock signals from the memory device, and receiving, at the controller, a second plurality of data signals and a third plurality of clock signals corresponding to a second portion of the first plurality of clock signals from the memory device.

### PRIORITY INFORMATION

This application claims the benefit of U.S. Provisional Application No. 63/602,034, filed on Nov. 22, 2023, the contents of which are incorporated herein by reference.

### TECHNICAL FIELD

Embodiments of the disclosure relate generally to memory sub-systems, and more specifically, relate to command signal clock toggling by a controller.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example computing system that includes a memory sub-system in accordance with some embodiments of the disclosure.

FIG. 2 illustrates a system for command signal clock toggling by a controller in accordance with some embodiments of the disclosure.

FIG. 3 is a flow diagram corresponding to a method for command signal clock toggling in accordance with some embodiments of the disclosure.

FIG. 4 is a block diagram of an example computer system in which embodiments of the disclosure may operate.

### DETAILED DESCRIPTION

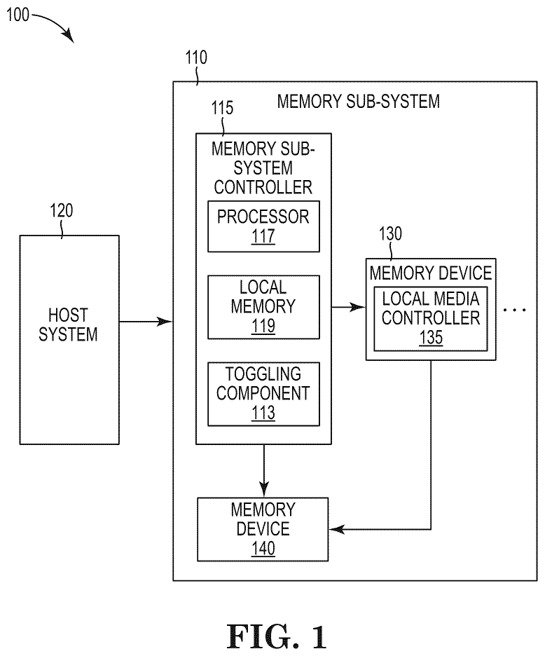

Aspects of the present disclosure are directed to command signal clock toggling by a controller, in particular to memory sub-systems that include a toggling component. A memory sub-system can be a storage system, storage device, a memory module, or a combination of such. An example of a memory sub-system is a storage system such as a solid-state drive (SSD). Examples of storage devices and memory modules are described below in conjunction with FIG. 1, et alibi. In general, a host system can utilize a memory sub-system that includes one or more components, such as memory devices that store data. The host system can provide data to be stored at the memory sub-system and can request data to be retrieved from the memory sub-system.

A memory device can be a non-volatile memory device. One example of non-volatile memory devices is a negative-and (NAND) memory device (also known as flash technology). As used herein, a NAND memory device can include either a set of flash memory dice or a combination of the flash memory dice and a non-volatile memory (NVM) controller. The NVM controller can include circuitry for performing read/write operations as described herein. Other examples of non-volatile memory devices are described below in conjunction with FIG. 1. A non-volatile memory device is a package of one or more dice. Each die can consist of one or more planes. Planes can be grouped into logic units (LUN). For some types of non-volatile memory devices (e.g., NAND devices), each plane consists of a set of physical blocks. Each block consists of a set of pages. Each page consists of a set of memory cells (“cells”). A cell is an electronic circuit that stores information. A block hereinafter refers to a unit of the memory device used to store data and can include a group of memory cells, a word line group, a word line, or individual memory cells. For some memory devices, blocks (also hereinafter referred to as “memory blocks”) are the smallest area that can be erased. Pages cannot be erased individually, and only whole blocks can be erased.

Each of the memory devices can include one or more arrays of memory cells. Depending on the cell type, a cell can be written to in order to store one or more bits of binary information, and has various logic states that correlate to the number of bits being stored. The logic states can be represented by binary values, such as “0” and “1”, or combinations of such values. There are various types of cells, such as single-level cells (SLCs), multi-level cells (MLCs), triple level cells (TLCs), and quad-level cells (QLCs). For example, a SLC can store one bit of information and has two logic states.

Some NAND memory devices employ a floating-gate architecture in which memory accesses are controlled based on a relative voltage change between the bit line and the word lines. Other examples of NAND memory devices can employ a replacement-gate architecture that can include the use of word line layouts that can allow for charges corresponding to data values to be trapped within memory cells based on properties of the materials used to construct the word lines.

In some previous approaches, a first-in, first-out (FIFO) device can be utilized to buffer communication between a memory device and a controller during read operations and/or write operations. A FIFO device can be utilized to buffer communication signals between devices that operate at different speeds or utilize independent clock signals. The FIFO device can be utilized to increase bandwidth and prevent data loss during high-speed communications. In some embodiments, a FIFO device can release data from the buffer in the order of its arrival. That is, a signal can be provided to an input of a FIFO device and be released at an output of the FIFO device in the order it was received at the input of the FIFO device.

In such approaches, the input of the FIFO device can be coupled to a flip-flop circuit. In general, a flip-flop circuit or latch circuit is a circuit that has two stable states and can be used to store state information. The flip-flop circuit can be made to change state by signals applied to one or more control inputs and will have one or two outputs. In this way, the flip-flop circuit can change state information each time a signal is received at the input of the flip-flop circuit. In some embodiments, the FIFO device can include a plurality of stages or storage locations to store a signal received at the input of the FIFO device from an output of the flip-flop circuit. The plurality of stages can each be utilized to store a corresponding state based on a signal received. When the FIFO device receives an additional signal, the previous signal is moved to the next stage until the signal is moved to the output of the FIFO device. In this way, a signal received at the input of the FIFO device can be “pushed” through each of the plurality of stages when additional signals are received at the input of the FIFO device from the flip-flop circuit until the signal is directed to an output of the FIFO device.

In previous approaches, the FIFO device is positioned within the physical layer (PHY) of the memory device. In these approaches, data signals (DQ signals, command data signals, etc.) can be provided by a memory device such as a NAND device. Furthermore, strobe signals (DQS signals, clock signals, etc.) can be provided to a memory device by a controller device. In response, DQS signals can be generated for each DQ signal provided by the memory device to the controller. In this way, output data can be generated at the flip-flop circuit based on the received command data signal and clock signal at the flip-flop circuit in response to a command data request signal from the controller. The output data can be provided to the FIFO device to be provided to the controller in an order it was received at the FIFO device. In some embodiments, output data, DQ signals, and/or DQS signals can be trapped within the flip-flop circuit and/or FIFO device when the memory device and/or controller stop providing signals to the input of the flip-flop circuit. In this way, a delay can occur in processing the command data signals from the memory device.

Aspects of the present disclosure address the above and other deficiencies by employing command signal clock toggling by a controller. For instance, the present disclosure can utilize a plurality of flip-flop circuits inside the PHY that are coupled to pipeline stages of a FIFO device placed outside the PHY or within an ASIC voltage domain. This configuration can allow for increased real estate for the FIFO device compared to other configurations, such as those employed in previous approaches. As used herein, the real estate refers to a physical area for positioning components on a memory device. In these embodiments, the controller can generate extra clock signals that are used to push data through the flip-flop circuits and the pipeline stages of the FIFO device. The extra clock signals provided to the NAND device allow the NAND device to generate extra command data clock signals that correspond to the extra command data signals. In this way, the command data corresponding to the command data signals that remain in the FIFO device can be pushed through the FIFO device to be processed. In these embodiments, the extra command data signals and clock signals can be flagged to be ignored as “garbage data” when processed since the command data signals do not correspond to data stored on the NAND device.

FIG. 1 illustrates an example computing system 100 that includes a memory sub-system 110 in accordance with some embodiments of the disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130, 140 can include one or more arrays of memory cells. One type of memory cell, for example, single-level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, a MLC portion, a TLC portion, a QLC portion, and/or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 130 can be based on any other type of non-volatile memory or storage device, such as such as, read-only memory (ROM), phase change memory (PCM), self-selecting memory, other chalcogenide based memories, ferroelectric transistor random access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

As described above, the memory components can be memory dice or memory packages that form at least a portion of the memory device 130. In some embodiments, the blocks of memory cells can form one or more “superblocks.” As used herein, a “superblock” generally refers to a set of data blocks that span multiple memory dice and are written in an interleaved fashion. For instance, in some embodiments each of a number of interleaved NAND blocks can be deployed across multiple memory dice that have multiple planes and/or pages associated therewith. The terms “superblock,” “block,” “block of memory cells,” and/or “interleaved NAND blocks,” as well as variants thereof, can, given the context of the disclosure, be used interchangeably.

The memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can be a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 130. The memory sub-system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

In some embodiments, the memory sub-system 110 can include a cache or buffer (e.g., DRAM) and address circuitry (e.g., a row decoder and a column decoder) that can receive an address from the memory sub-system controller 115 and decode the address to access the memory device 130 and/or the memory device 140. For instance, in some embodiments, the memory device 140 can be a DRAM and/or SRAM configured to operate as a cache for the memory device 130. In such instances, the memory device 130 can be a NAND.

In some embodiments, the memory device 130 includes local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local media controller 135) for media management within the same memory device package. An example of a managed memory device is a managed NAND (MNAND) device. The memory sub-system 110 can also include additional circuitry or components that are not illustrated.

The memory sub-system 110 can include a toggling component 113, which may be referred to in the alternative as a “controller,” herein. Although not shown in FIG. 1 so as to not obfuscate the drawings, the toggling component 113 can include various circuitry to facilitate aspects of media management, as detailed herein. In some embodiments, the toggling component 113 can include special purpose circuitry in the form of an ASIC, FPGA, state machine, and/or other logic circuitry that can allow the toggling component 113 to orchestrate and/or perform the operations described herein.

In some embodiments, the memory sub-system controller 115 includes at least a portion of the toggling component 113. For example, the memory sub-system controller 115 can include a processor 117 (processing device) configured to execute instructions stored in local memory 119 for performing the operations described herein. In some embodiments, the toggling component 113 is part of the memory sub-system 110, an application, or an operating system.

In a non-limiting example, an apparatus (e.g., the computing system 100) can include a toggling component 113. The toggling component 113 can be resident on the memory sub-system 110. As used herein, the term “resident on” refers to something that is physically located on a particular component. For example, the toggling component 113 being “resident on” the memory sub-system 110 refers to a condition in which the hardware circuitry that comprises the toggling component 113 is physically located on the memory sub-system 110. The term “resident on” can be used interchangeably with other terms such as “deployed on” or “located on,” herein.

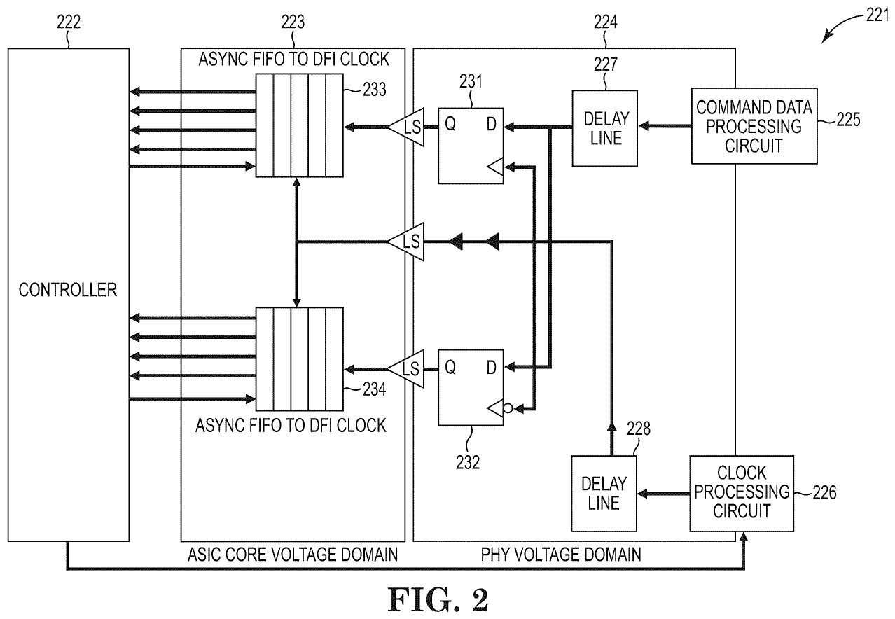

As described further herein with reference to FIG. 2, the memory sub-system 110 can include a first flip-flop circuit to receive data signals from a command data processing circuit. In these embodiments, the memory sub-system 110 can include a second flip-flop circuit to receive clock signals from a clock processing circuit. In some embodiments, the memory sub-system 110 can include a first first-in first-out (FIFO) device to receive a first output data from the first flip-flop circuit and a second FIFO device to receive a second output data from the second flip-flop circuit. In this way, the input of the first flip-flop circuit can be coupled to a command data processing circuit and the output of the first flip-flop circuit is coupled to an input of the first FIFO device. In addition, the input of the second flip-flop circuit can be coupled to a clock processing circuit and the output of the second flip-flop circuit can be coupled to the second FIFO device.

The toggling component 113 can be configured to generate a plurality of command signals to be provided to a memory device (e.g., memory device 130, etc.) to generate command data in response to the plurality of command signals. Command signals can be signals that are communicated in a status command/address (SCA) mode. For example, a controller can send command signals via a command/address (CA) pin to a memory device to read a status or determine other features of the memory device. In this example, the controller or host system 120 can send command data signals and command clock signals to the memory device.

In this example, the memory device can respond with command data signals and corresponding command clock signals. In some embodiments, the command data signals and corresponding command clock signals can be read by the controller to determine the status or other features of the memory device during the SCA mode. In some embodiments, the command data signals and the corresponding command clock signals from the memory device are sent to the host system and sampled by the controller.

The toggling component 113 can be configured to generate a first plurality of clock signals that correspond to the plurality of command signals to be provided to the memory device. As described herein, the first plurality of command signals can be generated with a first plurality of clock signals. In these embodiments, the first plurality of command signals and the corresponding first plurality of clock signals can be sent to a memory device during a SCA mode. In this way, for each command signal of the plurality of command signals can include a corresponding clock signal of the first plurality of clock signals.

The toggling component 113 can be configured to generate a second plurality of clock signals that exceed a quantity of the plurality of command signals to be provided to the memory device. In some embodiments, the protocol associated with SCA communication does not specify that the quantity of clock signals needs to be the same as the quantity of command signals. In this way, the toggling component 113 can generate a greater quantity of clock signals than the command signals to be sent to the memory device. For example, the quantity of command signals can be less than the combined quantity of the first plurality of clock signals and the second plurality of clock signals. In a specific example, the plurality of command signals can be equal to the first plurality of clock signals and the second plurality of clock signals can be excess clock signals that do not have corresponding command signals.

In these embodiments, the memory device can generate clock signals in response to the first plurality of clock signals and the second plurality of clock signals to be provided to a flip-flop circuit. In some embodiments, the memory device can generate clock signals in response to the first plurality of clock signals and the second plurality of clock signals according to an SCA protocol. In some embodiments, the memory device can generate command data signals based on data stored at the memory device in response to the plurality of command signals generated by the toggling component 113. In this way, the memory device can respond to the plurality of command signals with the plurality of command data signals that can be sampled by the controller (e.g., toggling component 113, etc.).

In some embodiments, the memory device can generate clock signals in response to the second plurality of clock signals. As described herein, the second plurality of clock signals generated by the toggling component 113 may not correspond to command signals or request signals. In this way, the toggling component 113 can provide additional clock signals to the memory resource such that the memory resource responds with corresponding additional clock signals. As described herein, a communication pathway between the memory device and the toggling component 113 can include a plurality of flip-flop circuits and/or a plurality of first-in first-out (FIFO) devices. In some embodiments, the plurality of flip-flop circuits can be utilized to sample the command data signals received by the memory device.

As described further in reference to FIG. 2, the communication pathway can include a first flip-flop circuit to receive command data from a command data processing circuit of a memory device, a second flip-flop circuit to receive clock signals from a clock processing circuit of the memory device, a first first-in first-out (FIFO) device to receive output command data from the first flip-flop circuit, and a second FIFO device to receive output clock data from the second flip-flop circuit. In these embodiments, the first FIFO device and/or the second FIFO device can store a plurality of bits prior to releasing the bits in the order received. In these embodiments, the bits can be trapped within the FIFO device when additional signals are not provided to the FIFO device.

In some embodiments, the first flip-flop circuit and the second flip-flop circuit are positioned on a physical layer of the apparatus and the first FIFO device and the second FIFO device are positioned off the physical layer of the apparatus. In some embodiments, the first flip-flop circuit is coupled to the first FIFO device by a first plurality of pipeline stages and the second flip-flop circuit is coupled to the second FIFO device by a second plurality of pipeline stages.

In some embodiments, the second plurality of clock signals can be provided to the memory device to generate response clock signals from the memory device to push data out of the first FIFO device and/or the second FIFO device. In these embodiments, the second plurality of clock signals can be generated based on a quantity of bits stored by the first FIFO device and/or the second FIFO device such that command data signals provided by the memory device are pushed through the first FIFO device and/or second FIFO device such that the command data signals are not trapped within the first FIFO device and/or the second FIFO device.

In some embodiments, the toggling component 113 can be configured to calculate a quantity of the second plurality of clock signals based on a quantity of bits utilized by the first FIFO device and the second FIFO device. As described herein, the quantity of the second plurality of clock signals can be utilized to push data through the first FIFO device and/or the second FIFO device. In this way, the toggling component 113 can calculate the quantity of the second plurality of clock signals such that command data signals that correspond to the command signals provided to the memory device are pushed through the first FIFO device and/or the second FIFO device.

In some embodiments, the toggling component 113 and/or the local media controller 135 can be configured to count the second plurality of clock signals that exceed the quantity of the plurality of command signals. In some embodiments, the memory device can include a counter device to count the quantity of clock signals that exceed the quantity of command signals received from the toggling component 113. In some embodiments, the toggling component 113 and/or the local media controller 135 can be configured to flag data associated with the second plurality of clock signals to the clock processing circuit as garbage data. In this way, the memory device can respond with corresponding clock signals and garbage data based on the second plurality of clock signals. As used herein, garbage data refers to data signals that do not correspond to data bits stored at the memory device. In this way, the garbage data does not represent stored data of the memory device.

In some embodiments, the toggling component 113 and/or the local media controller 135 can be configured to perform a clock reset in response to receiving a final clock signal from the second plurality of clock signals. As used herein, a clock reset can be performed by the memory device to alter a status of the memory device to receive signals from a host. In some embodiments, the clock reset can be an indication that the SCA mode has ended.

In some embodiments, the plurality of command signals include a command out header signal and a command de-assertion signal. In some embodiments, the command out header signal can initiate the SCA mode and a command de-assertion signal can stop the SCA mode. In these embodiments, the host or toggling component 113 can send any number of clock pulses between the command out header and the command de-assertion signal. As used herein, the command de-assertion signal can be when the command signal is changed to a high signal.

In some embodiments, the toggling component 113 can be configured to generate a first plurality of clock signals that correspond to a first plurality of command signals and a second plurality of clock signals, provide the first plurality of clock signals, the second plurality of clock signals, and the plurality of command signals to the non-volatile memory device, receive, at a first-in first-out (FIFO) device, a second plurality of command signals that correspond to the first plurality of command signals and a third plurality of clock signals that correspond to the first plurality of clock signals, receive, at the FIFO device, a third plurality of command signals and a fourth plurality of clock signals that correspond to the second plurality of clock signals, identify a first set of output values based on the received second plurality of command signals and the third plurality of clock signals within the FIFO device, and ignore a second set of output values based on the third plurality of command signals and the fourth plurality of clock signals.

In some embodiments, the toggling component 113 can be configured to calculate a quantity of the second plurality of clock signals based on a quantity of bits associated with the FIFO device. As described herein, the second plurality of clock signals can be based on the quantity of bits associated with a FIFO device such that command data corresponding to data stored at the memory device is pushed through the FIFO device. In some embodiments, the fourth plurality of clock signals push the first set of output values out of the FIFO device. In some embodiments, the toggling component 113 can be configured to send a command de-assertion signal to a non-volatile memory device after a fourth plurality of clock signals.

FIG. 2 illustrates system 221 for command signal clock toggling by a controller 222 in accordance with some embodiments of the disclosure. In some embodiments, the system 221 can include similar components or elements as the memory system 110 of FIG. 1. In some embodiments, the controller 222 can be at least a portion of the toggling component 113 of FIG. 1.

The system 221 can include a PHY voltage domain 224 and an application-specific integrated circuit (ASIC) core voltage domain 223. As described herein, the PHY voltage domain 224 can be a physical layer of the electrical circuit of the system 221. In these embodiments, the ASIC core voltage domain 223 can include an integrated circuit customized for a specific purpose. In these embodiments, the system 221 can include a first FIFO device 233 and a second FIFO device 234 positioned (e.g., deployed) within the ASIC core voltage domain 223. In these embodiments, the system 221 includes a first flip-flop circuit 231 and a second flip-flop circuit 232 that are positioned on the PHY voltage domain 224. As described herein, previous approaches can position the first FIFO device 233 and the second FIFO device 234 within the PHY voltage domain. In this way, the present disclosure moves the first FIFO device 233 and the second FIFO device 234 from the PHY voltage domain 224 to the ASIC core voltage domain 223.

The system 221 can include a command data processing circuit 225 to provide command data signals from a NAND or other type of memory device. The command data processing circuit 225 can comprise various hardware circuitry that can be configured to provide the command data signals to a delay line 227. The delay line 227 can be an arbiter or similar circuitry to ensure that signals are not provided to a device simultaneously or substantially simultaneously. The command signals can be provided to the first flip-flop circuit 231 and/or the second flip-flop circuit 232. In some embodiments, the first flip-flop circuit 231 can store a first value corresponding to a first command data signal received from the delay line 227. In these embodiments, the first flip-flop circuit 231 can provide the first value to the first FIFO device 233 upon receiving a second command data signal received from the delay line 227. In this embodiment, the first flip-flop circuit 231 can store a second value corresponding to the second command data signal and store the second value until a subsequent command data signal is received by the first flip-flop circuit 231.

In a similar way, the system 221 can include a clock processing circuit 226 to provide clock signals from a memory device in response to clock signals provided to the memory device by the controller 222. The clock processing circuit 226 can comprise various hardware circuitry that can be configured to provide the clock signals to a delay line 228. The delay line 228 can be an arbiter or similar circuitry to ensure that signals are not provided to a device simultaneously or substantially simultaneously. In some embodiments, the clock signals from the delay line 228 are provided to a NAND gate 229 that can receive clock signals from the clock processing circuit 226. In some embodiments, the command data processing circuit 225 can command data signals from a memory device in response to command data signals provided to the memory device.

As described herein, the clock processing circuit 226 can include hardware to send clock signals to a memory device and/or receive clock signals from the memory device. For example, the controller 222 can provide a first plurality of clock signals to the clock processing circuit 226 to be provided to a memory device. In this example, the clock processing circuit 226 can provide the clock signals from the memory device to the delay line 228.

The clock signals can be provided to the second flip-flop circuit 232 and/or the first flip-flop circuit 231. In some embodiments, the second flip-flop circuit 232 can store a first value of a first clock signal received from the NAND gate 229. In these embodiments, the second flip-flop circuit 232 can provide the first value to the second FIFO device 234 upon receiving a second clock signal received from the NAND gate 229. In this embodiment, the second flip-flop circuit 232 can store a second value corresponding to the second clock signal and store the second value until a subsequent clock signal is received by the second flip-flop circuit 232.

In some embodiments, the first FIFO device 233 and the second FIFO device 234 can include a number of stages such that data received at an input is transferred through each of the stages before being transferred out of the corresponding FIFO device to the controller 222. For example, the first FIFO device 233 can include four stages. Although four stages are described, any number of stages can be utilized in a similar way. In this example, the first FIFO device 233 can receive a first value (e.g., state) or first command data signal from the first flip-flop circuit 231. The first value can be stored at a first stage of the first FIFO device 233. In this example, the first FIFO device can receive a second value (e.g., state) or second command data signal from the first flip-flop circuit 231. The first FIFO device 233 can push the first value to the second stage and store the second value at the first stage. For each value received at the first FIFO device 233, the received value can be stored at the first stage and the other values can be pushed to the next stage until the value is pushed out of the fourth stage and to the controller 222. The second FIFO device 234 can operate in a similar way as the first FIFO device 233 when receiving clock signals from the NAND gate 229.

In some embodiments, the controller 222 can be configured to identify an output value based on the plurality of command data signals and the plurality of clock signals applied to a FIFO device. In some embodiments, the output value can be a value that is stalled or trapped within the FIFO device. The controller 222 may be able to identify a trapped output value within the FIFO device based on a quantity of command data signals and clock signals provided to the command data processing circuit 225 and clock processing circuit 226 respectively. For example, the command data signals and/or clock signals may be a quantity that will result in output data being trapped at a particular stage of the system 221. In some embodiments, the controller 222 can be configured to calculate a quantity of the additional clock signals based on a quantity of bits to be provided to the memory device and a quantity of bits utilized by the first FIFO device 233 and the second FIFO device 234.

As described herein, the size of the FIFO device can correspond to a maximum quantity of storage locations of the FIFO device and/or a quantity of stages associated with the FIFO device. In this way, the controller 222 can determine a quantity of additional clock signals and data signals needed to push the trapped data within the FIFO device out of the FIFO device. In this way, the controller 222 can generate a second plurality of clock signals to be provided to the clock processing circuit 226 to be provided to the memory device. In this example, the clock processing circuit 226 can receive corresponding clock signals from the memory device and provide the corresponding clock signals to the delay line 228.

In some embodiments, the memory device can provide command data to the command data processing circuit 225 for each of the additional clock signals generated by the controller 222. As described herein, the command data that corresponds to the additional clock signals can be garbage data that can be flagged or ignored by the controller 222.

As described herein, the process of pushing command data signals through the first flip-flop circuit 231 and first FIFO device 233 to the controller 222 and pushing the clock signals through the second flip-flop circuit 232 and the second FIFO device 234 can traditionally result in data being stalled within one or more of the first flip-flop circuit 231, first FIFO device 233, second flip-flop circuit, and/or the second FIFO device 234. For this reason, the present disclosure can utilize the controller 222 to provide additional clock signals to the clock processing circuit 226 through connection 235. In these embodiments, the additional clock signals from the controller 222 to the memory device may correspond to data that is to be ignored or identified as garbage data. The additional clock signals from the controller 222 through the connection 235 can be utilized to push stalled data through the second flip-flop circuit 232 and/or the second FIFO device 234.

In some embodiments, the controller 222 can determine a quantity of additional clock signals to provide based on a quantity of data stalled within the second flip-flop circuit 232 and/or the second FIFO device 234. That is, the controller 222 can determine a quantity of additional clock signals needed to push a last received clock signal from the clock processing circuit 226 through the second flip-flop circuit 232 and/or the second FIFO device 234. In some embodiments the additional clock signals can be tagged or flagged by the controller 222 as non-usable signals or signals to be ignored.

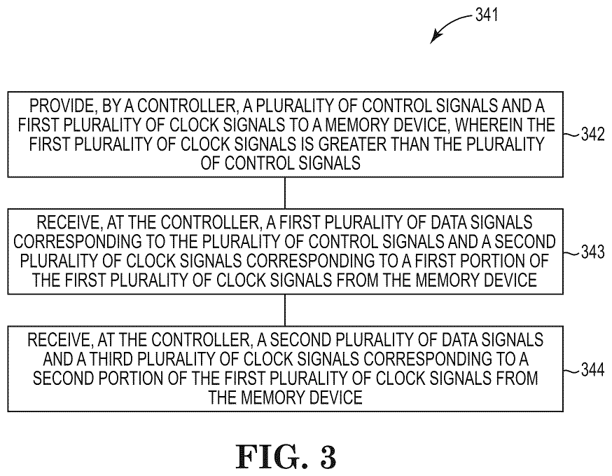

FIG. 3 is a flow diagram corresponding to a method 341 for command signal clock toggling in accordance with some embodiments of the disclosure. The method 341 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 341 is performed by the toggling component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 342, the method 341 can be executed to provide, by a controller, a plurality of control signals and a first plurality of clock signals to a memory device. In these embodiments, the first plurality of clock signals is greater than the plurality of control signals. In some embodiments, the control signals can be command signals that are generated during an SCA mode of operation by the controller. As described herein, the command signals can be utilized to determine a status or state of the memory device. The plurality of control signals can include a command out header.

At operation 343, the method 341 can be executed to receive, at the controller, a first plurality of data signals corresponding to the plurality of control signals and a second plurality of clock signals corresponding to a first portion of the first plurality of clock signals from the memory device. As described herein, the first plurality of data signals can be sampled by the controller to determine a response to the control signals generated by the controller. In some embodiments, the second plurality of clock signals can correspond to the clock signals that correspond to the control signals. In this way, the first portion of the first plurality of clock signals can correspond to the control signals.

At operation 344, the method 341 can be executed to receive, at the controller, a second plurality of data signals and a third plurality of clock signals corresponding to a second portion of the first plurality of clock signals from the memory device. As described herein, the second plurality of data signals can be generated by the memory device in response to receiving additional clock signals that exceed the quantity of control signals. For example, the second plurality of data signals can be garbage data that does not correspond to data stored by the memory device. In these embodiments, the second plurality of data signals and the third plurality of clock signals can be utilized to push the first plurality of data signals through a FIFO device.

In some embodiments, the method 341 can be executed to determine, at the memory device, a quantity of control signals received from the controller. In some embodiments, the memory device can identify a command out header received from the controller. In these embodiments, the quantity of control signals can be determined to identify a quantity of the second plurality of clock signals. In this way, the memory device can respond to the second plurality of clock signals with clock signals and garbage data to push the command data signals through a FIFO device.

In some embodiments, the method 341 can be executed to generate, at the controller, the first portion of the first plurality of clock signals based on a quantity of the plurality of control signals and the second portion of the first plurality of clock signals based on a pathway between the controller and the memory device. As described herein, the pathway between the controller and the memory device can include a plurality of flip-flop circuits and/or FIFO devices. In this way, the controller can provide excess clock signals to the memory device such that the memory device will provide garbage data and clock signals to push the signals through the flip-flop circuits and/or FIFO devices.

In some embodiments, the first plurality of data signals corresponding to the plurality of control signals correspond to values stored by the memory device. As described herein, the first plurality of data signals can be response data to the control signals that are stored by the memory device. In this way, the control signals can be sent to the memory device to determine a status of the memory device. In these embodiments, the first plurality of data signals can represent the status of the memory device.

In some embodiments, the second plurality of data signals corresponding to the second portion of the first plurality of clock signals do not correspond to values stored by the memory device. As described herein, the second plurality of data signals can be garbage data that are generated without corresponding data stored by the memory device. In these embodiments, the memory device can generate the second plurality of data signals to correspond with the third plurality of clock signals.

In some embodiments, the method 341 can be executed to generate, by the controller, a quantity of the second portion of the first plurality of clock signals based on a first-in first-out (FIFO) device positioned between the controller and the memory device. In these embodiments, the second plurality of data signals and the third plurality of clock signals move the first plurality of data signals through the FIFO device to the controller.

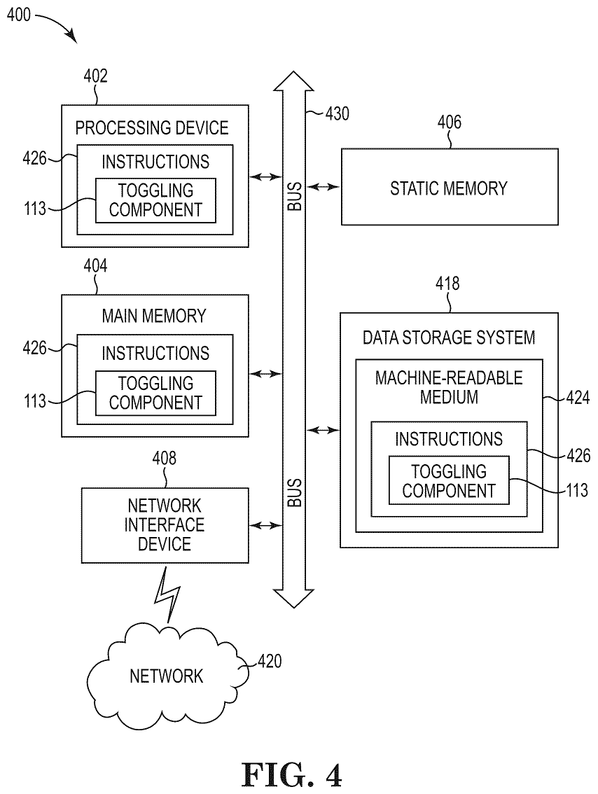

FIG. 4 is a block diagram of an example computer system 400 in which embodiments of the disclosure may operate. For example, FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the toggling component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a data storage system 418, which communicate with each other via a bus 430.

The processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a toggling component (e.g., the toggling component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer).

In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc. In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are. accordingly, to be regarded in an illustrative sense rather than a restrictive sense.

What is claimed is:

1. A method comprising:
providing, by a controller, a plurality of control signals and a first plurality of clock signals to a memory device, wherein the first plurality of clock signals is greater than the plurality of control signals;
receiving, at the controller, a first plurality of data signals corresponding to the plurality of control signals and a second plurality of clock signals corresponding to a first portion of the first plurality of clock signals from the memory device; and
receiving, at the controller, a second plurality of data signals and a third plurality of clock signals corresponding to a second portion of the first plurality of clock signals from the memory device.

2. The method of claim 1, further comprising determining, at the memory device, a quantity of control signals received from the controller.

3. The method of claim 1, further comprising generating, at the controller, the first portion of the first plurality of clock signals based on a quantity of the plurality of control signals and the second portion of the first plurality of clock signals based on a pathway between the controller and the memory device.

4. The method of claim 1, wherein the first plurality of data signals corresponding to the plurality of control signals correspond to values stored by the memory device.

5. The method of claim 1, wherein the second plurality of data signals comprise garbage data.

6. The method of claim 1, wherein the second plurality of data signals corresponding to the second portion of the first plurality of clock signals do not correspond to values stored by the memory device.

7. The method of claim 1, further comprising generating, by the controller, a quantity of the second portion of the first plurality of clock signals based on a first-in first-out (FIFO) device positioned between the controller and the memory device.

8. The method of claim 7, wherein the second plurality of data signals and the third plurality of clock signals move the first plurality of data signals through the FIFO device to the controller.

9. An apparatus, comprising:
a memory device interface comprising:
a first flip-flop circuit to receive command data from a command data processing circuit of a memory device;
a second flip-flop circuit to receive clock signals from a clock processing circuit of the memory device;
a first first-in first-out (FIFO) device to receive output command data from the first flip-flop circuit; and
a second FIFO device to receive output clock data from the second flip-flop circuit; and
a controller configured to:
generate a plurality of command signals to be provided to a memory device to generate command data in response to the plurality of command signals;
generate a first plurality of clock signals that correspond to the plurality of command signals to be provided to the memory device; and
generate a second plurality of clock signals that exceed a quantity of the plurality of command signals to be provided to the memory device, wherein the memory device is to generate clock signals in response to the first plurality of clock signals and the second plurality of clock signals to be provided to the second flip-flop circuit.

10. The apparatus of claim 9, wherein the controller is further configured to calculate a quantity of the second plurality of clock signals based on a quantity of bits utilized by the first FIFO device and the second FIFO device.

11. The apparatus of claim 9, wherein the memory device is further configured to count the second plurality of clock signals that exceed the quantity of the plurality of command signals.

12. The apparatus of claim 11, wherein the memory device is further configured to perform a clock reset in response to receiving a final clock signal from the second plurality of clock signals.

13. The apparatus of claim 9, wherein the first flip-flop circuit and the second flip-flop circuit are positioned on a physical layer of the apparatus and the first FIFO device and the second FIFO device are positioned off the physical layer of the apparatus.

14. The apparatus of claim 9, wherein the first flip-flop circuit is coupled to the first FIFO device by a first plurality of pipeline stages and the second flip-flop circuit is coupled to the second FIFO device by a second plurality of pipeline stages.

15. The apparatus of claim 9, wherein the plurality of command signals include a command out header signal and a command de-assertion signal.

16. The apparatus of claim 9, wherein the memory device is configured to flag data associated with the second plurality of clock signals to the clock processing circuit as garbage data.

17. A system comprising:
a memory sub-system comprising a non-volatile memory device; and
a processing device coupled to the memory sub-system, wherein the processing device is configured to:
generate a first plurality of clock signals that correspond to a first plurality of command signals and a second plurality of clock signals;
provide the first plurality of clock signals, the second plurality of clock signals, and the plurality of command signals to the non-volatile memory device;
receive, at a first-in first-out (FIFO) device, a second plurality of command signals that correspond to the first plurality of command signals and a third plurality of clock signals that correspond to the first plurality of clock signals
receive, at the FIFO device, a third plurality of command signals and a fourth plurality of clock signals that correspond to the second plurality of clock signals;
identify a first set of output values based on the received second plurality of command signals and the third plurality of clock signals within the FIFO device; and
ignore a second set of output values based on the third plurality of command signals and the fourth plurality of clock signals.

18. The system of claim 17, wherein the processing device is further configured to calculate a quantity of the second plurality of clock signals based on a quantity of bits associated with the FIFO device.

19. The system of claim 17, wherein the fourth plurality of clock signals push the first set of output values out of the FIFO device.

20. The system of claim 17, wherein the processing device is further configured to send a command de-assertion signal to the non-volatile memory device after the fourth plurality of clock signals.
